(19) United States
(12) Patent Application Publication
(10) Pub. No.: US 2010/0051901 A1
(43) Pub. Date: Mar. 4, 2010

(54) Light emitting devices and displays with improved performance

(76) Inventors: Peter T. Kazlas, Sudbury, MA (US); Marshall Cox, North Haven, CT (US); Seth Coe-Sullivan, Belmont, MA (US); Dorai Ramprasad, Columbia, MD (US); Jonathan S. Steckel, Bedford, MA (US); Craig Breen, Somerville, MA (US); Caroline J. Roush, Somerville, MA (US); Mead Misic, Medford, MA (US)

Correspondence Address: Martha Ann Finnegan;QD Vision, Inc., 4th Floor, 313 Pleasant Street, Watertown, MA, 02472, US

(21) Appl. No.: 12/454,705

(22) Filed: May 21, 2009

Related U.S. Application Data
(63) Continuation of application No. PCT/US07/24310, filed on Nov. 21, 2007.
(60) Provisional application No. 60/866,840, filed on Nov. 21, 2006.
(60) Provisional application No. 60/866,826, filed on Nov. 21, 2006.
(60) Provisional application No. 60/886,262, filed on Jan. 23, 2007.
(60) Provisional application No. 60/866,833, filed on Nov. 21, 2006.

(51) Int. Cl. H01L 33/00

(52) U.S. Cl. 257/13; 257/E33.008; 977/773; 977/949

(57) ABSTRACT

Light emitting devices and devices with improved performance are disclosed. In one embodiment, a light emitting device includes an emissive material disposed between a first electrode, and a second electrode, wherein the emissive material comprises semiconductor nanocrystals capable of emitting light including a maximum peak emission in the blue region of the spectrum upon excitation, wherein the light emitting device can have a peak external quantum efficiency of at least about 1.0 percent. Also disclosed is a display including at least one light emitting device including an emissive material disposed between a first electrode, and a second electrode, wherein the at least one light emitting device can have a peak external quantum efficiency of at least about 1.0 percent. In another embodiment, a light emitting device includes an emissive material disposed between a first electrode and a second electrode. The emissive material comprises semiconductor nanocrystals capable of emitting light including a maximum peak emission in the blue region of the spectrum upon excitation. The device further includes a first spacer material disposed between the emissive material and the first electrode. In certain embodiments, the device further includes a first material capable of transporting charge disposed between the emissive material and the first electrode, wherein the first spacer material is disposed between the emissive material and the first electrode. In certain embodiments, for example, light emitting devices can have a maximum peak emission in a range from about 380 nm to about 500 nm. In certain embodiments, the light emitting device can have a maximum peak emission peak in the range from about 450 nm to about 490 nm. Displays including light emitting devices are also disclosed.

This application is a continuation of commonly owned PCT Application No. PCT/US2007/024310 filed 21 Nov. 2007, which was published in the English language as PCT Publication No. WO 2008/063657 on 29 May 2008. The PCT Application claims priority to U.S. Application Nos. 60/886,262, filed 23 Jan. 2007, 60/866,826, filed 21 Nov. 2006, 60/866,840, filed 21 Nov. 2006, and 60/866,833, filed 21 Nov. 2006. The disclosures of each of the foregoing applications are hereby incorporated herein by reference in their entireties.

### TECHNICAL FIELD

The present invention relates to light emitting devices including semiconductor nanocrystals, and displays including light emitting devices including semiconductor nanocrystals.

### SUMMARY OF THE INVENTION

The present invention relates to light emitting devices and displays with improved performance.

In accordance with one aspect of the present invention, there is provided a light emitting device. A light emitting device includes an emissive material disposed between a first electrode and a second electrode. The emissive material comprises semiconductor nanocrystals capable of emitting light including a maximum peak emission in the blue region of the spectrum upon excitation. In certain embodiment, the light emitting device can have a peak external quantum efficiency of at least 1%. In certain embodiment, the light emitting device can have a peak external quantum efficiency of at least 1.3%. In certain embodiments, the light emitting device can have an external quantum efficiency of at least about 0.5 percent when measured at a current density of 5 mA/cm². In certain embodiments, the light emitting device can have an external quantum efficiency of at least about 0.1 percent when measured at a current density of 5 mA/cm². In certain embodiments, the device can further include at least one layer comprising a material capable of transporting charge. In certain embodiments, the emissive material can be disposed as one or more separate layers. In certain embodiments, the emissive material can be included in a layer comprising a matrix material disposed between the two electrodes. In certain embodiments, for example, the light emitting device can have a maximum peak emission in a range from about 380 nm to about 500 nm. In certain embodiments, for example, the light emitting device can have a maximum peak emission in a range from about 450 nm to about 490 nm. In certain embodiments, for example, the light emitting device can have a maximum peak emission at a wavelength no greater than about 470 nm.

In accordance with another aspect of the present invention, there is provided a display including at least one light emitting device including an emissive material disposed between a first electrode, and a second electrode. The emissive material comprises semiconductor nanocrystals capable of emitting light including a maximum peak emission in the blue region of the spectrum upon excitation. The light emitting device can have a peak external quantum efficiency of at least 0.5%. In certain embodiment, the light emitting device can have a peak external quantum efficiency of at least 1%. In certain embodiments, at least one light emitting device can further include at least one layer comprising a material capable of transporting charge. In certain embodiments, the emissive material can be disposed as one or more separate layers. In certain embodiments, the emissive material can be included in a layer comprising a matrix material disposed between the two electrodes. In certain embodiments, for example, the light emitting device can have a maximum peak emission in a range from about 380 nm to about 500 nm. In certain embodiments, for example, the light emitting device can have a maximum peak emission in a range from about 450 nm to about 490 nm. In certain embodiments, for example, the light emitting device can have a maximum peak emission at a wavelength no greater than about 470 nm.

In accordance with another aspect of the present invention, there is provided a light emitting device comprising an emissive material disposed between a first electrode and a second electrode. The emissive material comprises semiconductor nanocrystals capable of emitting light upon excitation. The device further includes a first spacer material disposed between the first electrode and the second electrode. In certain embodiments, the spacer material can be disposed between the emissive material and the first or second electrode. In certain embodiments, the device further includes a first material capable of transporting charge disposed between the first electrode and the second electrode. In certain embodiments, the first material capable of transporting charge is disposed between emissive material and the first electrode and the first spacer material disposed between the emissive material and the first electrode. As discussed below, optionally, additional layers can be further included in the device. In certain embodiments, the emissive material comprises semiconductor nanocrystals capable of emitting light including a maximum peak emission in the blue region of the spectrum upon excitation. In certain embodiments, the light emitting device can have a maximum peak emission in a range from about 380 nm to about 500 nm. In certain embodiments, the light emitting device can have a maximum peak emission in a range from about 450 nm to about 490 nm. In certain embodiments, the light emitting device can have a maximum peak emission at a wavelength no greater than about 470 nm.

In accordance with another aspect of the present invention, there is provided a light emitting device. The light emitting device includes an emissive material disposed between a first electrode and a second electrode. The emissive material comprises semiconductor nanocrystals capable of emitting light including a maximum peak emission in the blue region of the spectrum upon excitation. The device further includes a first material capable of transporting charge disposed between the emissive material and the first electrode and a first spacer material disposed between the emissive material and the first electrode.

In certain embodiments, the light emitting device can have a maximum peak emission in a range from about 380 nm to about 500 nm. In certain embodiments, the light emitting device can have a maximum peak emission in a range from about 450 nm to about 490 nm. In certain embodiments, the light emitting device can have a maximum peak emission at a wavelength no greater than about 470 nm.

In certain embodiments, the first material capable of transporting charge comprises a material capable of transporting holes.

In certain embodiments, the first material capable of transporting charge comprises a material capable of transporting electrons.

In certain embodiments, the first material capable of transporting charge can include first spacer material. In certain embodiments, first spacer material is dispersed or mixed in the first material capable of transporting charge. In certain embodiments, the dispersion or mixture is homogeneous. In certain embodiments, the dispersion or mixture is non-homogeneous. In certain embodiments, the concentration of first spacer in the first material capable of transporting charge comprises a concentration gradient. In certain embodiments, the highest concentration of first spacer material in the gradient is proximate to the emissive material.

In certain preferred embodiments, the first spacer material is included in the device as a layer. In certain more preferred embodiments, the first spacer material separates the emissive material from the first material capable of transporting charge.

In additional embodiments, the device further includes a second material capable of transporting charge disposed between the emissive material and the other of the electrodes and second spacer material between the emissive material and the second material capable of transporting charge.

In certain embodiments including a first material capable of transporting charge and a second materials capable of transporting charge, one of the first and second materials capable of transporting charge comprises a material capable of transporting holes and the other comprises a material capable of transporting electrons.

In certain embodiments, the second material capable of transporting charge can include second spacer material. In certain embodiments, second spacer material is dispersed or mixed in the second material capable of transporting charge. In certain embodiments, the dispersion or mixture is homogeneous. In certain embodiments, the dispersion or mixture is non-homogeneous. In certain embodiments, the concentration of second spacer in the second material capable of transporting charge comprises a concentration gradient. In certain embodiments, the highest concentration of second spacer material in the gradient is proximate to the emissive material.

In certain preferred embodiments, the second spacer material is included in the device as a layer. In certain more preferred embodiments, the second spacer material separates the emissive material from the second material capable of transporting charge.

In certain embodiments, a spacer material comprises a semiconductor material having a bandgap greater than the bandgap of the semiconductor nanocrystals capable of emitting light in the blue region of the spectrum included in the emissive material. In certain embodiments, the spacer material has a bandgap greater than or equal to 2.7 eV. In certain more embodiments, the spacer material has a bandgap greater than or equal to 3.2 eV. In certain embodiments, the spacer material comprises an insulating material. In certain embodiments, a spacer material can be inorganic. In certain embodiments, a spacer material can be organic.

In certain embodiments, a spacer material can include one or more different semiconductor or insulating materials. In certain embodiments, a spacer material can be doped with from about 10 to 50 weight percent charge transport material. In certain embodiments, a spacer material can be doped with from about 20 to 30 weight percent charge transport material.

In certain embodiments, a spacer material is optically inactive and electrically inactive when the emissive material is electrically excited.

In embodiments including a first and second spacer material, the first and second spacer material can be the same or different.

As discussed above, in certain embodiments, a spacer material can be included in the device as one or more separate layers. In certain embodiments including a spacer material comprising a insulating material disposed as a layer, the thickness of the layer is selected to be from 1 to 50 nm. In certain preferred embodiments, the thickness of a layer of spacer material comprising semiconductor material is less than 20 nm, more preferably, from 5 to 20 nm, and most preferable from 10 to 20 nm.

In certain embodiments including a spacer material comprising an semiconducting material disposed as a layer, thickness is not constrained by the same considerations as a semiconductor material. Thicker layers are possible, which can facilitate manufacturability. In certain embodiments, a spacer material comprising a semiconductor material can be from 1 nm to 1 micron, preferably up to 50 nm.

A material capable of transporting charge can include one or more different materials.

In certain embodiments, a material capable of transporting charge can be disposed as one or more separate layers.

In certain embodiments, the emissive material can be disposed as one or more separate layers. In certain embodiments, the emissive material can be included in a layer comprising a matrix material disposed between the two electrodes. In certain embodiments, for example, the light emitting device can have a maximum peak emission in a range from about 380 nm to about 500 nm. In certain embodiments, for example, the light emitting device can have a maximum peak emission in the range from about 450 nm to about 490 nm. In certain embodiments, for example, the light emitting device can have a maximum peak emission at a wavelength no greater than about 470 nm.

In accordance with another aspect of the present invention, there is provided a display including at least one light emitting device including an emissive material disposed between a first electrode and a second electrode. The emissive material comprises semiconductor nanocrystals capable of emitting light including a maximum peak emission in the blue region of the spectrum upon excitation. The device further includes a first material capable of transporting charge disposed between the emissive material and one of the electrodes and a first spacer material between the emissive material and the first material capable of transporting charge. The at least one light emitting device can comprise any of the other embodiments of described above.

In certain embodiments, for example, the blue light emitting device can have a maximum peak emission in a range from about 380 nm to about 500 nm. In certain embodiments, for example, the light emitting device can have a maximum peak emission in a range from about 450 nm to about 490 nm. In certain embodiments, for example, the light emitting device can have a maximum peak emission at a wavelength no greater than about 470 nm.

Examples of semiconductor nanocrystals that are capable of emitting blue light upon excitation (e.g., electrical excitation) that may be useful in various aspects and embodiments of the inventions described or contemplated by this general description, the following detailed description, and claims are described in U.S. Provisional Patent Application No. 60/866,826, filed 21 Nov. 2006, entitled “Blue Light Emitting Semiconductor Nanocrystal Materials And Compositions And Devices Including Same”, of Craig Breen et al.; the disclosure of which is hereby incorporated herein by reference in its entirety. Additional examples of semiconductor nanocrystals that are capable of emitting blue light upon excitation that may be useful in certain embodiments of the inventions described or contemplated by this general description, the following detailed description, and claims are described in U.S. Provisional Patent Application No. 60/866,840, filed 21 Nov. 2006, entitled “Blue Light Emitting Semiconductor Nanocrystal And Compositions And Devices Including Same”, of Dorai Ramprasad the disclosure of which is hereby incorporated herein by reference in its entirety.

In certain embodiments, a semiconductor nanocrystal that is capable of emitting blue light upon excitation can comprise a first semiconductor material comprising at least three chemical elements. In certain embodiments, the semiconductor nanocrystal can include a core comprising a first semiconductor material and a shell disposed over at least a portion of core, the shell comprising a second semiconductor material comprising at least three chemical element. In certain embodiments, the first semiconductor material can comprise zinc, cadmium, and selenium. In certain embodiments, the first semiconductor material can comprise Zn₁₋ₓCdₓSe, wherein 0≦x≦1. In certain embodiments, the second semiconductor material can comprise zinc, cadmium, and sulfur. In certain embodiments, the second semiconductor material can comprise CdₓZn₁₋ₓS wherein 0<x<1. In certain more detailed embodiments, the first semiconductor material can comprise Zn₁₋ₓCdₓSe, wherein 0<x<1, and the second semiconductor material can comprise CdₓZn₁₋ₓS wherein 0<x<1.

In certain embodiments, the semiconductor nanocrystal can comprise a first semiconductor material comprising cadmium, zinc and sulfur. In certain embodiments, the semiconductor nanocrystal can include a core comprising a first semiconductor material comprising cadmium, zinc and sulfur and a shell disposed over at least a portion of core, the shell comprising a second semiconductor material. In certain embodiments, a first semiconductor material can comprise ZnₓCd₁₋ₓS, wherein 0<x<1. In certain embodiments, 0<x≦0.5. In certain embodiments, 0<x≦0.3. In certain embodiments, 0.05<x<0.2. In certain embodiments, 0.1≦x≦0.15 In certain embodiments, x is from about 0.10 to about 0.12. In certain embodiments, a second semiconductor material can comprise zinc and sulfur. In certain embodiments, a second semiconductor material can comprise zinc sulfide.

In another aspect of the present invention there is provided a light emitting device including an emissive material comprising semiconductor nanocrystals disposed between a first electrode and a second electrode, and a second material disposed between the electrodes, wherein the second material is optically inactive and electrically inactive when the device is operating. In certain embodiments, the device can further include additional functional materials typically included in light emitting devices. In certain preferred embodiments, the second material is non-emissive when the device is operating.

In a further aspect of the invention, there is provided a display including at least one light emitting device including an emissive material comprising semiconductor nanocrystals disposed between a first electrode and a second electrode, and a second material disposed between the electrodes, wherein the second material is optically inactive and electrically inactive when the device is operating.

The foregoing, and other aspects described herein all constitute embodiments of the present invention.

It is to be understood that both the foregoing general description and the following detailed description are exemplary and explanatory only and are not restrictive of the invention as claimed. Other embodiments will be apparent to those skilled in the art from consideration of the description and drawings, from the claims, and from practice of the invention disclosed herein.

### BRIEF DESCRIPTION OF THE DRAWINGS

In the drawings:

FIG. 1 is a schematic drawing depicting a light emitting device.

FIGS. 2A & B are schematics drawing depicting a light emitting device. light emitting

FIG. 3 is a schematic drawing depicting a light emitting device

FIG. 4 depicts the arrangement of the pixels (including those designated as C1 and C2) included on test device coupons.

FIG. 5 depicts the normalized electroluminescence spectra of red, green and blue light emitting devices including semiconductor nanocrystals without spacer material (e.g., larger band gap spacer layers) between the semiconductor nanocrystal and charge transport layers.

FIG. 6 depicts the normalized electroluminescence spectra of red, green and blue light emitting devices including semiconductor nanocrystals with spacer material (e.g., larger band gap spacer layers) between the semiconductor nanocrystals and charge transport layers.

FIG. 7 depicts graphical representations of CIE coordinates, current density versus external quantum efficiency, emission wavelength versus intensity; and current density versus voltage for 2 different pixels (individual light emitting devices) (designated as C1 and C2) included on a certain Device Test Coupon of the examples.

FIG. 8 depicts graphical representations of CIE coordinates, current density versus external quantum efficiency, emission wavelength versus intensity; and current density versus voltage for 2 different pixels (individual light emitting devices) (designated as C1 and C2) included on a certain Device Test Coupon of the examples.

FIG. 9 depicts the normalized electroluminescence spectra of Device Test Coupons of the examples.

FIG. 10 depicts the normalized electroluminescence spectra of a certain Device Test Coupon of the examples.

The attached figures are simplified representations presented for purposes of illustration only; the actual structures may differ in numerous respects, including, e.g., relative scale, etc.

For a better understanding to the present invention, together with other advantages and capabilities thereof, reference is made to the following disclosure and appended claims in connection with the above-described drawings.

### DETAILED DESCRIPTION OF THE INVENTION

The invention relates to light emitting devices and displays with improved performance.

The light emitting device comprising an emissive material comprising semiconductor nanocrystals capable of emitting blue light upon electrical excitation can have an external quantum efficiency of at least about 1.0%. In certain embodiments, the light emitting device can have an external quantum efficiency of at least about 0.5% when measured at a current density of 5 mA/cm².

A display includes at least one light emitting device in accordance with various embodiments and aspects of the inventions described or contemplated by this general description, the following detailed description, and claims.

As used herein, “external quantum efficiency” (EQE) is the ratio of emitted light intensity to current flow (e.g., photons out/electrons in). EQE is described in more detail, including examples of how it is measured, in S. R. Forrest, D. D. C. Bradley, M. E. Thompson” “Measuring the Efficiency of Organic Light emitting Devices”, Advanced Materials, Volume 15, Issue 13, Pages 1043-1048 (2003 WILEY-VCH Verlag GmbH & Co. KGaA, Weinheim), which is hereby incorporated herein by reference in its entirety.

As used herein “peak external quantum efficiency” refers to the maximum measurable or recordable external quantum efficiency when plotted as current density vs. external quantum efficiency.

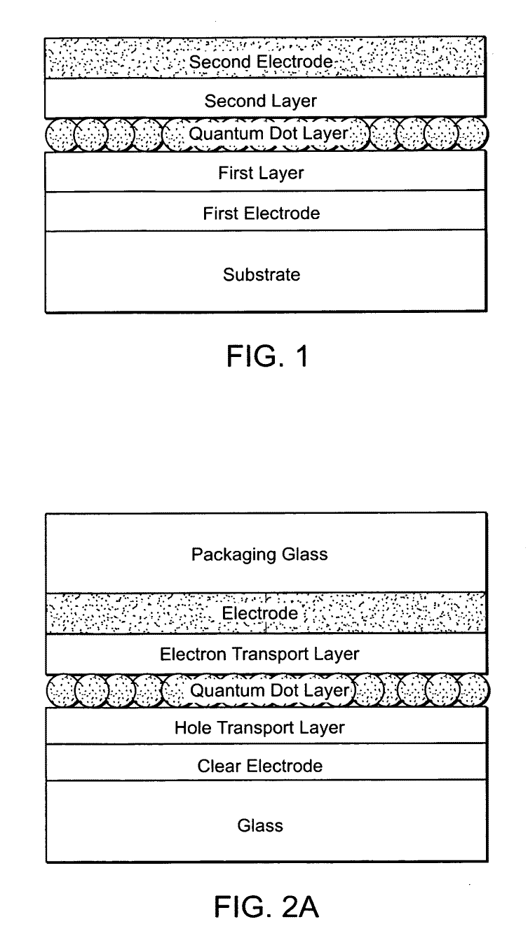

An example of an embodiment of a light emitting device is shown in FIG. 1. The depicted example includes a first electrode disposed over a substrate, a first layer in electrical connection with the first electrode, a second layer in electrical connection with the first layer, and a second electrode in electrical connection with the second layer. The first layer can comprise a material capable of transporting holes (HTL) and the second layer can comprise a material capable of transporting electrons (ETL). At least one layer can be non-polymeric. An emissive material is included between the two electrodes. The emissive material can include a plurality of semiconductor nanocrystals that can be selected based upon their light-emissive characteristics (e.g., the wavelength of the photon emitted by the nanocrystal when voltage is applied across the device). The emissive material can be included as one or more layers (as shown in FIG. 1) between the first layer and the second layer. A layer including an emissive material comprising a plurality of semiconductor nanocrystals can be a monolayer of semiconductor nanocrystals. Alternatively, the emissive material can be included in the first layer and/or second layer. In the embodiment depicted in FIG. 1 the first electrode of the structure is in contact with the substrate. Each electrode can be connected to a power supply to provide a voltage across the structure. Electroluminescence can be produced by the semiconductor nanocrystals included in the device when a voltage of proper polarity is applied across the heterostructure. As discussed herein, in certain embodiments (not shown), a device can include additional layers.

As described above, in certain embodiments, the first layer and/or the second layer can include an emissive material comprising a plurality of semiconductor nanocrystals, for example, a substantially monodisperse population of nanocrystals. Light emitting devices including an emissive material comprising a plurality of semiconductor nanocrystals can be made by spin-casting a solution containing the HTL organic semiconductor molecules and the semiconductor nanocrystals, where the HTL formed underneath of the semiconductor nanocrystal monolayer via phase separation (see, for example, U.S. patent application Ser. Nos. 10/400,907, filed Mar. 28, 2003, and U.S. Patent Application Publication No. 2004/0023010, each of which is incorporated by reference in its entirety). This phase separation technique can reproducibly place a monolayer of semiconductor nanocrystals between an organic semiconductor HTL and ETL, thereby effectively exploiting the favorable light emission properties of semiconductor nanocrystals, while minimizing their impact on electrical performance.

Making a light emitting device by this technique can be limited by impurities in the solvent, by the necessity to use organic semiconductor molecules that are soluble in the same solvents as the semiconductor nanocrystals. The phase separation technique can be unsuitable for depositing a monolayer of semiconductor nanocrystals on top of both a HTL and a HIL (due to the solvent destroying the underlying organic thin film). The phase separation method can also be unsuitable for controlling the location of semiconductor nanocrystals that emit different colors on the same substrate and for patterning of the different color emitting nanocrystals on that same substrate.

The device structure depicted in FIG. 1 may be fabricated as follows. A substrate having a first electrode (e.g., an anode) disposed thereon may be obtained or fabricated using any suitable technique. The first electrode may be patterned. A first layer (e.g., comprising a material capable of transporting holes) may be deposited using any suitable technique. An emissive layer can be deposited by spin-casting, drop-casting, Langmuir-Blodgett techniques, contact printing or other techniques known or readily identified by one skilled in the relevant art. A second layer (e.g., comprising a material capable of transporting electrons) may be deposited using any suitable technique. A second electrode (e.g., a cathode) may be deposited using any suitable technique.

In the example shown in FIG. 1, light is emitted from the bottom of the structure. If an adequately light transmissive top electrode is used, the structure could emit light from the top of the structure.

Alternatively, the structure of FIG. 1 can be inverted, in which case light can be emitted from the top.

The simple layered structure illustrated in FIG. 1 is provided by way of non-limiting example, and it is understood that embodiments of the invention may be used in connection with a wide variety of other structures. The specific materials and structures described herein are exemplary in nature, and other materials and structures may be used. Functional light emitting devices may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. Optionally, one or more of the layers can be patterned. For example, patterned layers (other than the emissive layer) can be deposited by vapor deposition using shadow masks or other masking techniques.

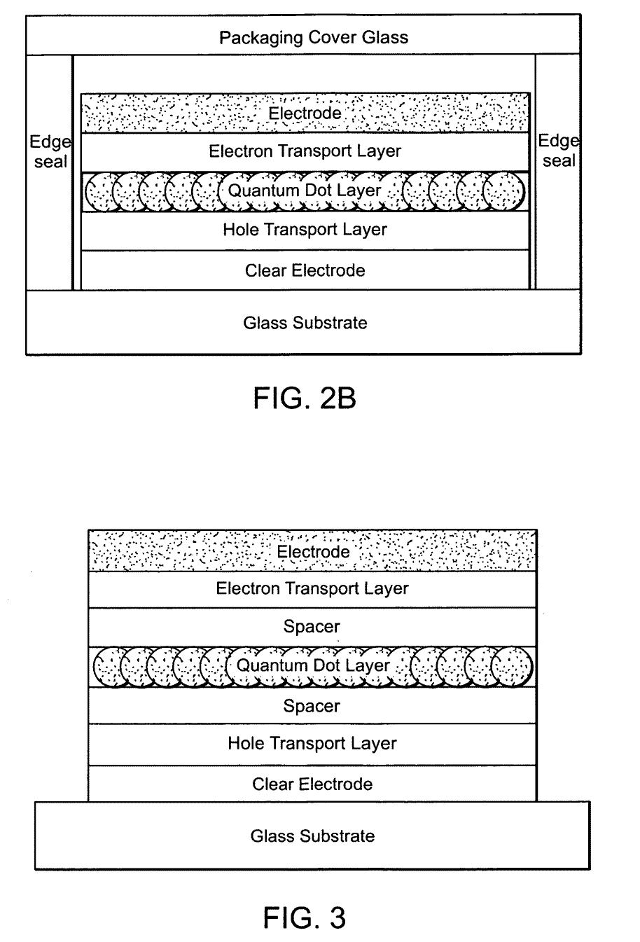

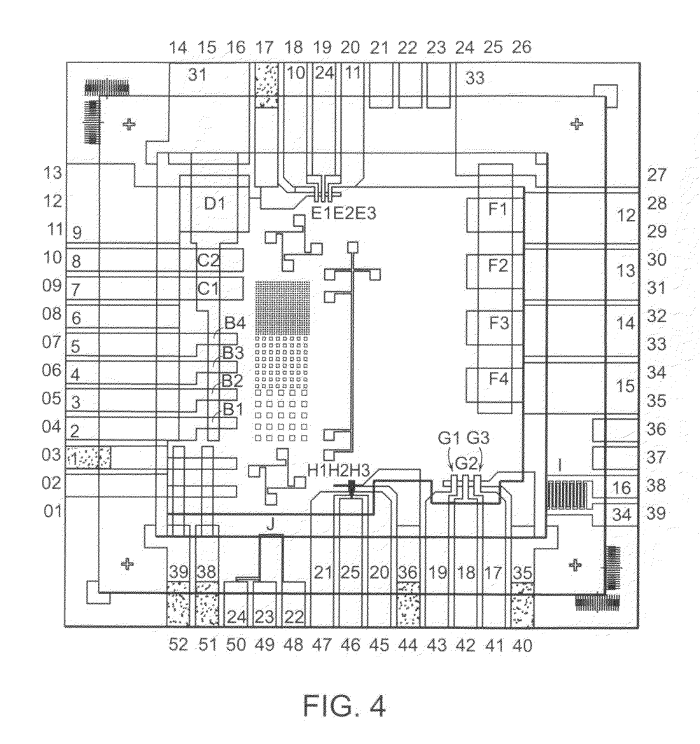

FIGS. 2 A & B illustrate examples of an embodiment of a light emitting device showing a glass substrate on which the device can be built and a protective layer. In the embodiment shown in FIG. 2A, a protective cover glass layer covers the surface of the device opposite the substrate. In the embodiment shown in FIG. 2B, a device can be protected by including a cover glass layer and protective edge seal (e.g., epoxy or other sealant material). Optionally a desiccant or other moisture absorptive material can be included in the device before it is sealed, e.g., with an epoxy, such as a UV curable epoxy. Other desiccants or moisture absorptive materials can be used. As discussed above, in another aspect of the present invention, a light emitting device includes an emissive material disposed between a first electrode and a second electrode. The device further includes a first material capable of transporting charge disposed between the emissive material and the first electrode and a first spacer material disposed between the emissive material and the first electrode. The emissive material comprises semiconductor nanocrystals capable of emitting light including a maximum peak emission in the blue region of the spectrum upon excitation.

In additional embodiments, the device further includes a second material capable of transporting charge disposed between the emissive material and the other of the electrodes and second spacer material between the emissive material and the second material capable of transporting charge.

In certain preferred embodiments, a spacer material with a bandgap larger than the band gap of the semiconductor nanocrystals can be disposed between a material capable of transporting holes and semiconductor nanocrystals. In certain embodiments, the spacer material can be included in the device as a layer.

In certain embodiments, spacer material is included in a layer that is located between an emissive material comprising semiconductor nanocrystals and a layer comprising a material capable of transporting holes. In certain embodiments, spacer material can be included in a layer disposed between a layer comprising a material capable of transporting electrons and the emissive material.

As discussed above, spacer material can comprise a semiconductor material having a bandgap greater than the bandgap of the semiconductor nanocrystals capable of emitting light in the blue region of the spectrum included in the emissive material. In certain embodiments, a spacer material can have a bandgap greater than or equal to 2.7 eV. In certain more embodiments, a spacer material can have a bandgap greater than or equal to 3.2 eV.

As used herein, a spacer material can provide a physical separation between charged transport molecules or materials in a device. In certain embodiments, the spacer material provides physical separation between charged transport molecules/materials by either doping or as a continuous film.

In certain preferred embodiments, a spacer material electrically and optically inactive.

In embodiments of the invention including semiconductor nanocrystals that are capable of emitting blue light under electrical excitation, the physical separation provided by the spacer can reduce the probability of organic emission from excited complexes or exciplexes thereby reducing unwanted emission.

Non-limiting examples of suitable organic spacer materials include organosilicon compounds [diphenyldi(o-tolyl)silane (UGH1), p-bis(triphenylsilyl)benzene (UGH2), m-bis(triphenylsilyl)benzene (UGH3), and 9,9′-spirobisilaanthracene (UGH4)], polymerized fluorocarbons, polylaurylmethacrylate (PLMA), polymethylmethacrylate (PMMA), polystyrene and parylene materials (see below).

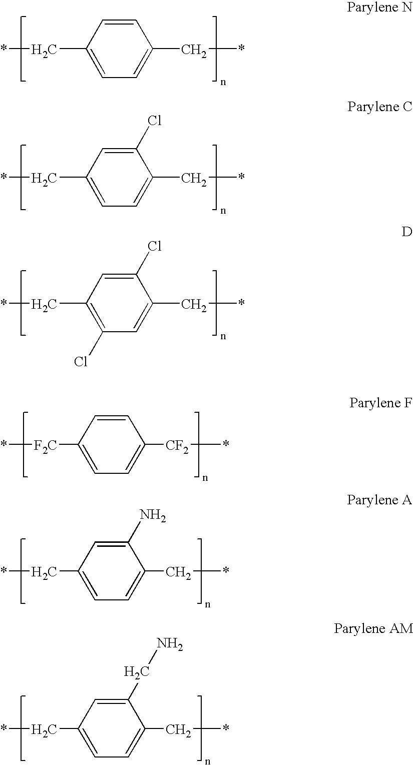

Non-limiting examples of suitable inorganic spacer materials include silicon monoxide, silicon dioxide, silicon nitride, zinc oxide and titanium oxide. These can be deposited by physical vapor deposition (PVD—e.g., thermal evaporation, sputtering), plasma-enhanced chemical vapor deposition (PECVD) or by sol-gel processes (spin-coating and thermal annealing step).

If aggressive (energetic) deposition techniques (such as plasma-based PVD or high temperature sol-gel processes) are used in device fabrication steps occurring after deposition of the emissive material, special care must be taken to avoid degradation of the emissive material fluorescence properties during subsequent processing steps.

In certain embodiments, a spacer material can comprise an insulating material. In certain embodiments, a spacer material can be inorganic. In certain embodiments, a spacer material can be organic. In certain embodiments, a spacer material can include one or more different semiconductor and/or insulating materials.

In an example of a device including a first and second spacer layer shown in FIG. 3, first spacer material is included in a first spacer layer that is disposed between a first charge transport layer (e.g., comprising a material capable of transporting holes) and the emissive material and second spacer material is included in a second spacer layer that is disposed between a second charge transport layer (e.g., comprising a material capable of transporting electrons) and the emissive material. In certain embodiments, the first and second spacer materials can be the same. In certain embodiments, the first and second spacer materials can be different. In certain embodiments, a spacer material can comprise an organic or inorganic material. In certain embodiments, a spacer material can be semiconducting or insulating material. In certain embodiments, a spacer material can be a single material. In certain embodiments, a spacer material can be doped with a different material (e.g., a charge transport molecules). In certain embodiments including a dopant, the spacer material is disposed as a layer including a concentration gradient doping profile between the charge transport material (either hole or electron transport layer) and the emissive material. In certain embodiments, the spacer layer can have gradient doping profile between the electrode (either anode or cathode) and the emissive material and most preferably doped with a charge transport molecule (either hole or electron transport molecule).

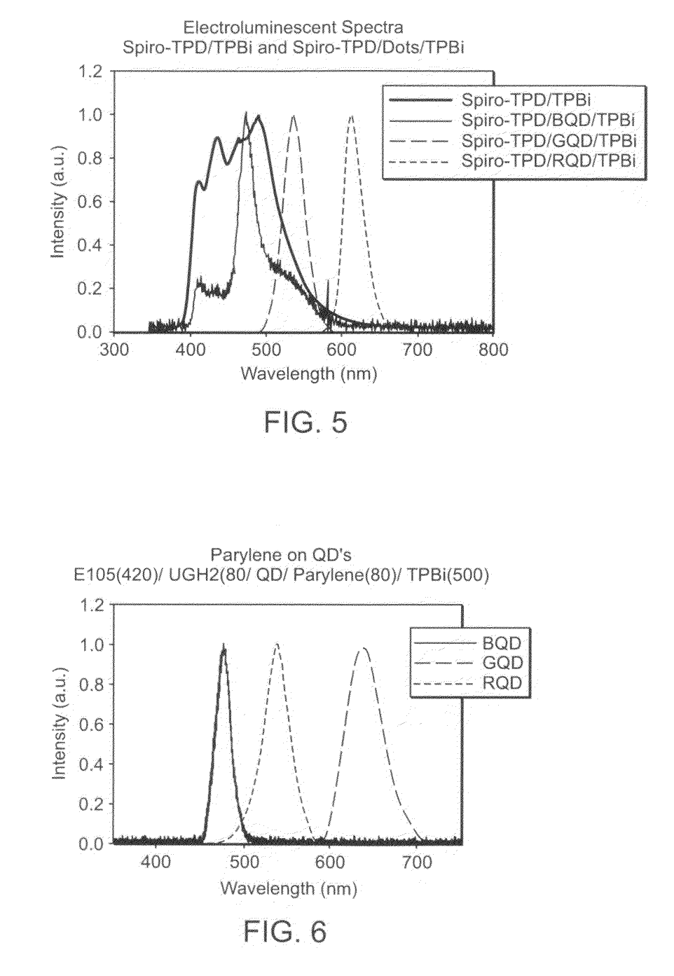

FIG. 5 depicts the color saturation of blue emission for a light emitting device without a spacer layer comprising spiro-TPD (E105) as a hole transport layer, semiconductor nanocrystals (quantum dots) and an electron transport layer (TPBi). FIG. 6 depicts the enhanced color saturation of blue emission for an embodiment of a light emitting device with spacer layers on both sides of the emissive material included as a layer in the device. The spacer material included between the hole transport layer (E105) and the semiconductor nanocrystal layer was 8 nm of UGH2 and the spacer material included between the electron transport layer (TPBi) and semiconductor nanocrystal layer was 8 nm of parylene. In certain most preferred embodiments, the blue emission includes no or substantially no exciplex emission (e.g., as evidence by a small shoulder or irregularity at the lower right side of the blue emission peak.)

In the various embodiments and aspects of the invention described herein, the color of the light output of a light emitting device can be precisely controlled by the selection of the composition, structure, and size of the various semiconductor nanocrystals included in a light emitting device as the emissive material. In certain embodiments, two or more different semiconductor nanocrystals (having different compositions, structures, and/or sizes) can be included.

Semiconductor nanocrystals include, for example, inorganic crystallites between about 1 nm and about 1000 nm in diameter, preferably between about 2 nm and about 50 nm, more preferably about 5 nm to about 20 nm (such as about 6, 7, 8, 9, 10, 11, 12, 13, 14, 15, 16, 17, 18, 19, or 20 nm).

The semiconductor forming the semiconductor nanocrystals can comprise a Group IV element, a Group II-VI compound, a Group II-V compound, a Group III-VI compound, a Group III-V compound, a Group IV-VI compound, a Group I-III-VI compound, a Group II-IV-VI compound, a Group II-IV-V compound, an alloy including any of the foregoing, and/or a mixture including any of the foregoing, including ternary and quaternary mixtures or alloys, for example, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TIAs, TlSb, PbO, PbS, PbSe, PbTe, Ge, Si, an alloy including any of the foregoing, and/or a mixture including any of the foregoing, including ternary and quaternary mixtures or alloys.

Examples of the shape of the semiconductor nanocrystals include sphere, rod, disk, other shape or mixtures thereof.

Preferably, the semiconductor nanocrystals include a “core” of one or more first semiconductor materials, which may be surrounded by an overcoating or “shell” of one or more second semiconductor materials. A semiconductor nanocrystal core surrounded by a semiconductor shell is also referred to as a “core/shell” semiconductor nanocrystal.

For example, the semiconductor nanocrystal can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of materials suitable for use as semiconductor nanocrystal cores include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TIAs, TlSb, PbO, PbS, PbSe, PbTe, Ge, Si, an alloy including any of the foregoing, and/or a mixture including any of the foregoing, including ternary and quaternary mixtures or alloys.

The shell can be a semiconductor material having a composition that is the same as or different from the composition of the core. The shell comprises an overcoat of a semiconductor material on a surface of the core semiconductor nanocrystal can include a Group IV element, a Group II-VI compound, a Group II-V compound, a Group III-VI compound, a Group III-V compound, a Group IV-VI compound, a Group I-III-VI compound, a Group II-IV-VI compound, a Group II-IV-V compound, alloys including any of the foregoing, and/or mixtures including any of the foregoing, including ternary and quaternary mixtures or alloys. Examples include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TlN, TlP, TIAs, TlSB, PbO, PbS, PbSe, PbTe, Ge, Si, an alloy including any of the foregoing, and/or a mixture including any of the foregoing. For example, ZnS, ZnSe or CdS overcoatings can be grown on CdSe or CdTe semiconductor nanocrystals. An overcoating process is described, for example, in U.S. Pat. No. 6,322,901. By adjusting the temperature of the reaction mixture during overcoating and monitoring the absorption spectrum of the core, over coated materials having high emission quantum efficiencies and narrow size distributions can be obtained. The overcoating may comprise one or more layers. The overcoating comprises at least one semiconductor material which is the same as or different from the composition of the core. Preferably, the overcoating has a thickness of from about one to about ten monolayers. An overcoating can also have a thickness greater than ten monolayers. In certain embodiments, more than one overcoating can be included on a core.

In certain embodiments, the surrounding “shell” material can have a band gap greater than the band gap of the core material. In certain embodiments, the surrounding shell material can have a band gap less than the band gap of the core material.

In certain embodiments, the shell can be chosen so as to have an atomic spacing close to that of the “core” substrate. In certain embodiments, the shell and core materials can have the same crystal structure.

Examples of semiconductor nanocrystal (core)shell materials include, without limitation: red (e.g., (CdSe)ZnS (core)shell), green (e.g., (CdZnSe)CdZnS (core)shell, etc.), and blue (e.g., (CdS)CdZnS (core)shell.

Additional examples of core/shell semiconductor structures are described in U.S. application Ser. No. 10/638,546, for “Semiconductor Nanocrystal Heterostructures”, filed 12 Aug. 2003, and U.S. Published Patent Application No. US 2004-0023010 A1, for “Light Emitting Device Including Semiconductor Nanocrystals” of Bulovic et al. The foregoing applications are hereby incorporated herein by reference in its entirety.

Preparation and manipulation of semiconductor nanocrystals are described, for example, in U.S. Pat. Nos. 6,322,901 and 6,576,291, and U.S. Patent Application No. 60/550,314, each of which is hereby incorporated herein by reference in its entirety. One method of manufacturing a semiconductor nanocrystal is a colloidal growth process. Colloidal growth occurs by injection an M donor and an X donor into a hot coordinating solvent. One example of a preferred method for preparing monodisperse semiconductor nanocrystals comprises pyrolysis of organometallic reagents, such as dimethyl cadmium, injected into a hot, coordinating solvent. This permits discrete nucleation and results in the controlled growth of macroscopic quantities of semiconductor nanocrystals. The injection produces a nucleus that can be grown in a controlled manner to form a semiconductor nanocrystal. The reaction mixture can be gently heated to grow and anneal the semiconductor nanocrystal. Both the average size and the size distribution of the semiconductor nanocrystals in a sample are dependent on the growth temperature. The growth temperature necessary to maintain steady growth increases with increasing average crystal size. The semiconductor nanocrystal is a member of a population of semiconductor nanocrystals. As a result of the discrete nucleation and controlled growth, the population of semiconductor nanocrystals that can be obtained has a narrow, monodisperse distribution of diameters. The monodisperse distribution of diameters can also be referred to as a size. Preferably, a monodisperse population of particles includes a population of particles wherein at least about 60% of the particles in the population fall within a specified particle size range. A population of monodisperse particles preferably deviate less than 15% rms (root-mean-square) in diameter and more preferably less than 10% rms and most preferably less than 5%.

In certain embodiments, the preparation of semiconductor nanocrystals can be carried out in the presence of an amine. See, for example, U.S. Pat. No. 6,576,291 for “Preparation of Nanocrsytallites” of Bawendi et al. issued 10 Jun. 2003, which is hereby incorporated herein by reference in its entirety.

The narrow size distribution of the semiconductor nanocrystals allows the possibility of light emission in narrow spectral widths. Monodisperse semiconductor nanocrystals have been described in detail in Murray et al. (J. Am. Chem. Soc., 115:8706 (1993)); in the thesis of Christopher Murray, “Synthesis and Characterization of II-VI Quantum Dots and Their Assembly into 3-D Quantum Dot Superlattices”, Massachusetts Institute of Technology, September, 1995; and in U.S. patent application Ser. No. 08/969,302 for “Highly Luminescent Color-Selective Materials”. The foregoing are hereby incorporated herein by reference in their entireties.

The process of controlled growth and annealing of the semiconductor nanocrystals in the coordinating solvent that follows nucleation can also result in uniform surface derivatization and regular core structures. As the size distribution sharpens, the temperature can be raised to maintain steady growth. By adding more M donor or X donor, the growth period can be shortened. The M donor can be an inorganic compound, an organometallic compound, or elemental metal. M is cadmium, zinc, magnesium, mercury, aluminum, gallium, indium or thallium. The X donor is a compound capable of reacting with the M donor to form a material with the general formula MX. The X donor can be a chalcogenide donor or a pnictide donor, such as a phosphine chalcogenide, a bis(silyl) chalcogenide, dioxygen, an ammonium salt, or a tris(silyl) pnictide. Suitable X donors include dioxygen, bis(trimethylsilyl) selenide ((TMS)₂Se), trialkyl phosphine selenides such as (tri-noctylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-noctylphosphine) sulfide (TOPS), an ammonium salt such as an ammonium halide (e.g., NH4Cl), tris(trimethylsilyl) phosphide ((TMS)₃P), tris(trimethylsilyl) arsenide ((TMS)₃As), or tris(trimethylsilyl) antimonide ((TMS)₃Sb). In certain embodiments, the M donor and the X donor can be moieties within the same molecule.

A coordinating solvent can help control the growth of the semiconductor nanocrystal. The coordinating solvent is a compound having a donor lone pair that, for example, has a lone electron pair available to coordinate to a surface of the growing semiconductor nanocrystal. Solvent coordination can stabilize the growing semiconductor nanocrystal. Examples of coordinating solvents include alkyl phosphines, alkyl phosphine oxides, alkyl phosphonic acids, or alkyl phosphinic acids, however, other coordinating solvents, such as pyridines, furans, and amines may also be suitable for the semiconductor nanocrystal production. Examples of suitable coordinating solvents include pyridine, tri-n-octyl phosphine (TOP), tri-n-octyl phosphine oxide (TOPO) and trishydroxylpropylphosphine (tHPP), tributylphosphine, tri(dodecyl)phosphine, dibutyl-phosphite, tributyl phosphite, trioctadecyl phosphite, trilauryl phosphite, tris(tridecyl) phosphite, triisodecyl phosphite, bis(2-ethylhexyl)phosphate, tris(tridecyl) phosphate, hexadecylamine, oleylamine, octadecylamine, bis(2-ethylhexyl)amine, octylamine, dioctylamine, trioctylamine, dodecylamine/laurylamine, didodecylamine tridodecylamine, hexadecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, dioctyl ether, diphenyl ether, methyl myristate, octyl octanoate, and hexyl octanoate. In certain embodiments, technical grade TOPO can be used.

Size distribution during the growth stage of the reaction can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystals. For example, for CdSe and CdTe, by stopping growth at a particular semiconductor nanocrystal average diameter and choosing the proper composition of the semiconducting material, the emission spectra of the semiconductor nanocrystals can be tuned continuously over the wavelength range of 300 nm to 5 microns, or from 400 nm to 800 nm.

The particle size distribution of the semiconductor nanocrystals can be further refined by size selective precipitation with a poor solvent for the semiconductor nanocrystals, such as methanol/butanol as described in U.S. Pat. No. 6,322,901. For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected semiconductor nanocrystal population preferably has no more than a 15% rms deviation from mean diameter, more preferably 10% rms deviation or less, and most preferably 5% rms deviation or less.

As discussed herein, the semiconductor nanocrystals preferably have ligands attached thereto.

In one embodiment, the ligands are derived from the coordinating solvent used during the growth process. The surface can be modified by repeated exposure to an excess of a competing coordinating group to form an overlayer. For example, a dispersion of the capped semiconductor nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the semiconductor nanocrystal, including, for example, phosphines, thiols, amines and phosphates. The semiconductor nanocrystal can be exposed to short chain polymers which exhibit an affinity for the surface and which terminate in a moiety having an affinity for a liquid medium in which the semiconductor nanocrystal is suspended or dispersed. Such affinity improves the stability of the suspension and discourages flocculation of the semiconductor nanocrystal.

The organic ligands can be useful in facilitating large area, non-epitaxial deposition of highly stable inorganic nanocrystals within a device.

More specifically, the coordinating ligand can have the formula:

(Y—)ₖ₋ₙ—(X)—(-L)ₙ

wherein k is 2, 3 4, or 5, and n is 1, 2, 3, 4 or 5 such that k-n is not less than zero; X is O, O—S, O—Se, O—N, O—P, O—As, S, S═O, SO2, Se, Se═O, N, N═O, P, P═O, C═O As, or As═O; each of Y and L, independently, is H, OH, aryl, heteroaryl, or a straight or branched C2-18 hydrocarbon chain optionally containing at least one double bond, at least one triple bond, or at least one double bond and one triple bond. The hydrocarbon chain can be optionally substituted with one or more C1-4 alkyl, C2-4 alkenyl, C2-4 alkynyl, C1-4 alkoxy, hydroxyl, halo, amino, nitro, cyano, C3-5 cycloalkyl, 3-5 membered heterocycloalkyl, aryl, heteroaryl, C1-4 alkylcarbonyloxy, C1-4 alkyloxycarbonyl, C1-4 alkylcarbonyl, or formyl. The hydrocarbon chain can also be optionally interrupted by —O—, —S—, —N(Ra)—, —N(Ra)—C(O)—O—, —O—C(O)—N(Ra)—, —N(Ra)—C(O)—N(Rb)—, —O—C(O)—O—, —P(Ra)—, or —P(O)(Ra)—. Each of Ra and Rb, independently, is hydrogen, alkyl, alkenyl, alkynyl, alkoxy, hydroxylalkyl, hydroxyl, or haloalkyl. An aryl group is a substituted or unsubstituted cyclic aromatic group. Examples include phenyl, benzyl, naphthyl, tolyl, anthracyl, nitrophenyl, or halophenyl. A heteroaryl group is an aryl group with one or more heteroatoms in the ring, for instance furyl, pyridyl, pyrrolyl, phenanthryl.

A suitable coordinating ligand can be purchased commercially or prepared by ordinary synthetic organic techniques, for example, as described in J. March, Advanced Organic Chemistry, which is hereby incorporated by reference in its entirety.

Other ligands are described in U.S. patent application Ser. No. 10/641,292 for “Stabilized Semiconductor Nanocrystals”, filed 15 Aug. 2003, which is hereby incorporated herein by reference in its entirety.

When the electron and hole localize on a semiconductor nanocrystal, emission can occur at an emission wavelength. The emission has a frequency that corresponds to the band gap of the quantum confined semiconductor material. The band gap is a function of the size of the semiconductor nanocrystal. Semiconductor nanocrystals having small diameters can have properties intermediate between molecular and bulk forms of matter. For example, semiconductor nanocrystals based on semiconductor materials having small diameters can exhibit quantum confinement of both the electron and hole in all three dimensions, which leads to an increase in the effective band gap of the material with decreasing crystallite size. Consequently, both the optical absorption and emission of semiconductor nanocrystals shift to the blue, or to higher energies, as the size of the crystallites decreases.

The emission from a semiconductor nanocrystal can be a narrow Gaussian emission band that can be tuned through the complete wavelength range of the ultraviolet, visible, or infra-red regions of the spectrum by varying the size of the semiconductor nanocrystal, the composition of the semiconductor nanocrystal, or both. For example, CdSe can be tuned in the visible region and InAs can be tuned in the infra-red region. The narrow size distribution of a population of semiconductor nanocrystals can result in emission of light in a narrow spectral range. The population can be monodisperse preferably exhibits less than a 15% rms (root-mean-square) deviation in diameter of the semiconductor nanocrystals, more preferably less than 10%, most preferably less than 5%. Spectral emissions in a narrow range of no greater than about 75 nm, preferably 60 nm, more preferably 40 nm, and most preferably 30 nm full width at half max (FWHM) for semiconductor nanocrystals that emit in the visible can be observed. IR-emitting semiconductor nanocrystals can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of semiconductor nanocrystal diameters decreases. Semiconductor nanocrystals can have high emission quantum efficiencies such as greater than about 10%, greater than about 20%, greater than about 30%, greater than about 40%, greater than about 50%, greater than about 60%, greater than about 70%, or greater than about 80%.

The narrow FWHM of semiconductor nanocrystals can result in saturated color emission. This can lead to efficient lighting devices even in the red and blue parts of the visible spectrum, since in semiconductor nanocrystal emitting devices no photons are lost to infra-red and UV emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of semiconductor nanocrystals will emit light spanning a narrow range of wavelengths. A device including semiconductor nanocrystals of different compositions, sizes, and/or structures can emit light in more than one narrow range of wavelengths. The color of emitted light perceived by a viewer can be controlled by selecting appropriate combinations of semiconductor nanocrystal sizes and materials in the device as well as relative subpixel currents. The degeneracy of the band edge energy levels of semiconductor nanocrystals facilitates capture and radiative recombination of all possible excitons, whether generated by direct charge injection or energy transfer. The maximum theoretical semiconductor nanocrystal lighting device efficiencies are therefore comparable to the unity efficiency of phosphorescent organic light emitting devices. The excited state lifetime (τ) of the semiconductor nanocrystal is much shorter (τ˜10 ns) than a typical phosphor (τ>0.1 μs), enabling semiconductor nanocrystal lighting devices to operate efficiently even at high current density and high brightness.

Transmission electron microscopy (TEM) can provide information about the size, shape, and distribution of the semiconductor nanocrystal population. Powder X-ray diffraction (XRD) patterns can provide the most complete information regarding the type and quality of the crystal structure of the semiconductor nanocrystals. Estimates of size are also possible since particle diameter is inversely related, via the X-ray coherence length, to the peak width. For example, the diameter of the semiconductor nanocrystal can be measured directly by transmission electron microscopy or estimated from X-ray diffraction data using, for example, the Scherrer equation. It also can be estimated from the UV/Vis absorption spectrum.

In certain embodiments, the emissive material can be deposited as one or more separate layers. In certain embodiments, a layer comprising emissive material can be disposed between any two layers of the device. For example, the layer comprising emissive material can be disposed between two hole transport layers and/or between two electron transport layers. In either case, each of the charge transport layers may further comprise one or more layers. In another embodiment, the emissive material can be deposited as one or more separate layers disposed between a hole transport layer and an electron transport layer. As discussed elsewhere herein, other layers may also be included between the electron transport layers and the hole transport layers. In another embodiment, the emissive material can be deposited as one or more separate layers disposed between a layer comprising spacer material and a layer comprising a material capable of transporting charge (e.g., a material capable of transporting holes or a material capable of transporting holes). When included in the device as a separate layer, for example, emissive material comprising a plurality of semiconductor nanocrystals can be disposed as a continuous or substantially continuous thin film or layer. When disposed as a separate layer, the layer can be patterned or unpatterned. Preferably, emissive material comprising a plurality of semiconductor nanocrystals comprises a substantially monodisperse population of semiconductor nanocrystals.

In certain embodiments, the emissive material comprising a plurality of semiconductor nanocrystals is deposited at a thickness of multiple monolayers or less. For example, the thickness can be greater than three monolayers, three or less monolayers, two or less monolayers, a single monolayer, a partial monolayer, etc. The thickness of each deposited layer of emissive material comprising a plurality of semiconductor nanocrystals may vary. Preferably, the variation of the thickness at any point of the deposited semiconductor nanocrystals is less than three monolayers, more preferably less than two monolayers, and most preferably less than one monolayer. When deposited as a single monolayer, preferably at least about 60% of the semiconductor nanocrystals are at single monolayer thickness, more preferably, at least about 80% of the semiconductor nanocrystals are at single monolayer thickness, and most preferably, at least about 90% of the semiconductor nanocrystals are at single monolayer thickness. In a light emitting device, a monolayer can provide the beneficial light emission properties of semiconductor nanocrystals while minimizing the impact on electrical performance. Semiconductor nanocrystals show strong quantum confinement effects that can be harnessed in designing bottom-up chemical approaches to create complex heterostructures with electronic and optical properties that are tunable with the size and composition of the semiconductor nanocrystals.

As discussed herein, in certain embodiments, emissive material comprising a plurality of semiconductor nanocrystals can be deposited in a patterned arrangement. Patterned semiconductor nanocrystals can be used to form an array of light emitting devices (or pixels) comprising, e.g., red, green, and blue, or alternatively, red, orange, yellow, green, blue-green, blue, violet, or other visible, infrared, or ultraviolet emitting, or other combinations of distinguishable wavelength emitting subpixels, that are energized to produce light of a predetermined wavelength.

An array of light emitting devices on a substrate may be referred to as a display; each light emitting device of a display may also be referred to as a pixel.

Generally, a device or array of devices capable of emitting a variety of colors includes a pattern of emissive materials capable of emitting different colors.

When deposited in a patterned arrangement, the emissive material can be deposited in a pattern comprising features having at least one dimension at a micron-scale (e.g., less than 1 mm, less than 500 μm, less than 200 μm, less than 100 μm or less, less than 50 μm or less, less than 20 μm or less). The emissive material can also be deposited in a patterned arrangement comprising features at greater than micron-scale.

A pattern comprising deposited emissive material having features on the micron scale may also be referred to herein as a micropattern. A micropattern can have features on the micron scale, such as less than 1 mm, less than 500 μm, less than 200 μm, less than 100 μm, less than 50 μm, or 20 μm or less in size. A 20 μm feature size or smaller is suitable for many light emitting devices.

The size of a display can have dimensions of >1 mm, 1 cm or greater, 10 cm or greater, 100 cm or greater, or 1,000 cm or greater.

For example, displays can have dimensions of small areas (for example, 100 μm square areas) to large areas, (for example, 12″ square areas). In further example, displays can be fabricated on mother glass having dimensions such as GEN2 (360 mm×465 mm), GEN3 (550 mm×650 mm), GEN3.5 (600 mm×720 mm), GEN4 (730 mm×920 mm), GEN5 (1110 mm×1250 mm), GEN6 (1500 mm×1800 mm), GEN7 (1900 mm×2100 mm), and subsequent generations of glass. Optionally, displays can be stitched (or tiled) together, to expand display sizes from 12″ squares, to ‘n×12″ squares’ as is frequently done in the semiconductor lithography field.

Contact printing provides a method for applying a material to a predefined region on a substrate. The predefined region is a region on the substrate where the material is selectively applied. The material and substrate can be chosen such that the material remains substantially entirely within the predetermined area. By selecting a predefined region that forms a pattern, material can be applied to the substrate such that the material forms a pattern. The pattern can be a regular pattern (such as an array, or a series of lines), or an irregular pattern. Once a pattern of material is formed on the substrate, the substrate can have a region including the material (the predefined region) and a region substantially free of material. In some circumstances, the material forms a monolayer on the substrate. The predefined region can be a discontinuous region. In other words, when the material is applied to the predefined region of the substrate, locations including the material can be separated by other locations that are substantially free of the material.

In some embodiments, contact printing can begin by forming a patterned or unpatterned mold. The mold has a surface with a pattern of elevations and depressions. The stamp can include planar and/or non-planar regions. A stamp is formed with a complementary pattern of elevations and depressions, for example by coating the patterned surface of the mold with a liquid polymer precursor that is cured while in contact with the patterned mold surface. The stamp can then be inked; that is, the stamp is contacted with a material which is to be deposited on a substrate. The material becomes reversibly adhered to the stamp. The inked stamp is then contacted with the substrate. The elevated regions of the stamp can contact the substrate while the depressed regions of the stamp can be separated from the substrate. Where the inked stamp contacts the substrate, the ink material (or at least a portion thereof) is transferred from the stamp to the substrate. In this way, the pattern of elevations and depressions is transferred from the stamp to the substrate as regions including the material and free of the material on the substrate. Microcontact printing and related techniques are described in, for example, U.S. Pat. Nos. 5,512,131; 6,180,239; and 6,518,168, each of which is incorporated by reference in its entirety. In some circumstances, the stamp can be a featureless stamp having a pattern of ink, where the pattern is formed when the ink is applied to the stamp. See U.S. patent application Ser. No. 11/253,612, filed Oct. 21, 2005, which is incorporated by reference in its entirety.

Other techniques, methods and applications that may be useful with the present invention are described in, U.S. Provisional Patent Application No. 60/792,170, of Seth Coe-Sullivan, et al., for “Composition Including Material, Methods Of Depositing Material, Articles Including Same And Systems For Depositing Material”, filed on 14 Apr. 2006; U.S. Provisional Patent Application No. 60/792,084, of Maria J. Anc, For “Methods Of Depositing Material, Methods Of Making A Device, And System”, filed on 14 Apr. 2006, U.S. Provisional Patent Application No. 60/792,086, of Marshall Cox, et al, for “Methods Of Depositing Nanomaterial & Methods Of Making A Device” filed on 14 Apr. 2006; U.S. Provisional Patent Application No. 60/792,167 of Seth Coe-Sullivan, et al, for “Articles For Depositing Materials, Transfer Surfaces, And Methods” filed on 14 Apr. 2006, U.S. Provisional Patent Application No. 60/792,083 of LeeAnn Kim et al., for “Applicator For Depositing Materials And Methods” filed on 14 Apr. 2006; U.S. Provisional Patent Application 60/793,990 of LeeAnn Kim et al., for “Applicator For Depositing Materials And Methods” filed by Express Mail on 21 Apr. 2006; U.S. Provisional Patent Application No. 60/790,393 of Seth Coe-Sullivan et al., for “Methods And Articles Including Nanomaterial”, filed on 7 Apr. 2006; U.S. Provisional Patent Application No. 60/805,735 of Seth Coe-Sullivan, for “Methods For Depositing Nanomaterial, Methods For Fabricating A Device, And Methods For Fabricating An Array Of Devices”, filed on 24 Jun. 2006; U.S. Provisional Patent Application No. 60/805,736 of Seth Coe-Sullivan et al., for “Methods For Depositing Nanomaterial, Methods For Fabricating A Device, Methods For Fabricating An Array Of Devices And Compositions”, filed on 24 Jun. 2006; U.S. Provisional Patent Application No. 60/805,738 of Seth Coe-Sullivan et al., for “Methods And Articles Including Nanomaterial”, filed on 24 Jun. 2006; U.S. Provisional Patent Application No. 60/804,921 of Seth Coe-Sullivan et al., for “Light emitting Devices And Displays With Improved Performance”, filed on 15 Jun. 2006; U.S. Provisional Patent Application No. 60/866,828 of Craig Breen et al., for “Semiconductor Nanocrystal Materials And Compositions And Devices Including Same,” filed 21 Nov. 2006; U.S. Provisional Patent Application No. 60/866,832 of Craig Breen et al. for “Semiconductor Nanocrystal Materials And Compositions And Devices Including Same,” filed 21 Nov. 2006; U.S. Provisional Patent Application No. 60/866,833 of Dorai Ramprasad for “Semiconductor Nanocrystal And Compositions And Devices Including Same” filed 21 Nov. 2006; U.S. Provisional Patent Application No. 60/866,834 of Dorai Ramprasad for “Semiconductor Nanocrystal And Compositions And Devices Including Same,” filed 21 Nov. 2006; U.S. Provisional Patent Application No, 60/866,839 of Dorai Ramprasad for “Semiconductor Nanocrystal And Compositions And Devices Including Same” filed 21 Nov. 2006; and U.S. Provisional Patent Application No. 60/866,843 of Dorai Ramprasad for “Semiconductor Nanocrystal And Compositions And Devices Including Same,” filed 21 Nov. 2006. Each of the above-listed provisional patent applications is hereby incorporated herein by reference in its entirety.

Light emitting devices in accordance with embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix addressing.

The first electrode can be, for example, an anode comprising a high work function (e.g., greater than 4.0 eV) hole-injecting conductor, such as an indium tin oxide (ITO) layer. Other anode materials include other high work function hole-injection conductors including, but not limited to, for example, tungsten, nickel, cobalt, platinum, palladium and their alloys, gallium indium tin oxide, zinc indium tin oxide, titanium nitride, polyaniline, or other high work function hole-injection conducting polymers. In certain embodiments, the first electrode is light transmissive or transparent. In addition to ITO, examples of other light-transmissive electrode materials include conducting polymers, and other metal oxides, low or high work function metals, conducting epoxy resins, or carbon nanotubes/polymer blends or hybrids that are at least partially light transmissive. An example of a conducting polymer that can be used as an electrode material is poly(ethlyendioxythiophene), sold by Bayer AG under the trade mark PEDOT. Other molecularly altered poly(thiophenes) are also conducting and could be used, as well as emaraldine salt form of polyaniline.

The second electrode can be, for example, a cathode comprising a low work function (e.g., less than 4.0 eV), electron-injecting, metal, such as Al, Ba, Yb, Ca, a lithium-aluminum alloy (Li:Al), a magnesium-silver alloy (Mg:Ag), or lithium fluoride-aluminum (LiF:Al). The second electrode, such as Mg:Ag, can optionally be covered with an opaque protective metal layer, for example, a layer of Ag for protecting the cathode layer from atmospheric oxidation, or a relatively thin layer of substantially transparent ITO. The second electrode can be sandwiched, sputtered, or evaporated onto the exposed surface of the solid layer. One or both of the electrodes can be patterned. The electrodes of the device can be connected to a voltage source by electrically conductive pathways. Upon application of the voltage, light is generated from the device.

In a device such as that shown in FIG. 1, for example, the first electrode can have a thickness of about 500 Angstroms to 4000 Angstroms. The first layer can have a thickness of about 50 Angstroms to about 1000 Angstroms. The second layer can have a thickness of about 50 Angstroms to about 1000 Angstroms. The second electrode can have a thickness of about 5 Angstroms to greater than about 10,000 Angstroms.

Non-polymeric electrode materials can be deposited by, for example, sputtering or evaporating. Polymeric electrode materials can be deposited by, for example, spin-casting.

As discussed above, the electrodes can be patterned. Electrode material, including light-transmittable electrode material, can be patterned by, for example, a chemical etching method such as a photolithography or a physical etching method using laser, etc. Also, the electrode may be patterned by vacuum vapor deposition, sputtering, etc. while masking.

Hole transport and electron transport layers can be collectively referred to as charge transport layers. Either or both of these layers can comprise organic or inorganic materials. Examples of inorganic material include, for example, inorganic semiconductors. The inorganic material can be amorphous or polycrystalline. An organic charge transport material can be polymeric or non-polymeric.

An example of a typical organic material that can be included in an electron transport layer includes a molecular matrix. The molecular matrix can be non-polymeric. The molecular matrix can include a small molecule, for example, a metal complex. The metal complex of 8-hydroxyquinoline can be an aluminum, gallium, indium, zinc or magnesium complex, for example, aluminum tris(8-hydroxyquinoline) (Alq₃). In certain embodiments, the electron transport material can comprise LT-N820 available from Luminescent Technologies, Taiwan. Other classes of materials in the electron transport layer can include metal thioxinoid compounds, oxadiazole metal chelates, triazoles, sexithiophenes derivatives, pyrazine, and styrylanthracene derivatives. An electron transport layer comprising an organic material may be intrinsic (undoped) or doped. Doping may be used to enhance conductivity. See, for example, U.S. Provisional Patent Application No. 60/795,420 of Beatty et al, for “Device Including Semiconductor Nanocrystals And A Layer Including A Doped Organic Material And Methods”, filed 27 Apr. 2006, which is hereby incorporated herein by reference in its entirety.

An examples of a typical organic material that can be included in a hole transport layer includes an organic chromophore. The organic chromophore can include a phenyl amine, such as, for example, N,N′-diphenyl-N,N′-bis(3-methylphenyl)-(1,1′-biphenyl)-4,4′-diamine (TPD). Other hole transport layer can include spiro-TPD, 4-4′-N,N′-dicarbazolyl-biphenyl (CBP), 4,4-.bis[N-(1-naphthyl)-N-phenylamino]biphenyl (NPD), etc., a polyaniline, a polypyrrole, a poly(phenylene vinylene), copper phthalocyanine, an aromatic tertiary amine or polynuclear aromatic tertiary amine, a 4,4′-bis(p-carbazolyl)-1,1′-biphenyl compound, or an N,N,N′,N′-tetraarylbenzidine. A hole transport layer comprising an organic material may be intrinsic (undoped) or doped. Doping may be used to enhance conductivity. Examples of doped hole transport layers are described in U.S. Provisional Patent Application No. 60/795,420 of Beatty et al, for “Device Including Semiconductor Nanocrystals And A Layer Including A Doped Organic Material And Methods”, filed 27 Apr. 2006, which is hereby incorporated herein by reference in its entirety.

Charge transport layers comprising organic materials and other information related to fabrication of organic charge transport layers are discussed in more detail in U.S. patent application Ser. Nos. 11/253,612 for “Method And System For Transferring A Patterned Material”, filed 21 Oct. 2005, and 11/253,595 for “Light Emitting Device Including Semiconductor Nanocrystals”, filed 21 Oct. 2005. The foregoing patent applications are hereby incorporated herein by reference in its entirety.

Organic charge transport layers may be disposed by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., ≦10⁻⁸ torr), high vacuum (e.g., from about 10⁻⁸ torr to about 10⁻⁵ torr), or low vacuum conditions (e.g., from about 10⁻⁵ torr to about 10⁻³ torr). Most preferably, the organic layers are deposited at high vacuum conditions of from about 1×10⁻⁷ to about 5×10⁻⁶ torr. Alternatively, organic layers may be formed by multi-layer coating while appropriately selecting solvent for each layer.

Charge transport layers including inorganic materials and other information related to fabrication of inorganic charge transport layers are discussed further below and in more detail in U.S. Patent Application No. 60/653,094 for “Light Emitting Device Including Semiconductor Nanocrystals”, filed 16 Feb. 2005 and U.S. patent application Ser. No. 11/354,185, filed 15 Feb. 2006, the disclosures of each of which are hereby incorporated herein by reference in their entireties.

Charge transport layers comprising an inorganic semiconductor can be deposited on a substrate at a low temperature, for example, by a known method, such as a vacuum vapor deposition method, an ion-plating method, sputtering, inkjet printing, etc.

The substrate can be opaque, light transmissive, or transparent. The substrate can be rigid or flexible. The substrate can comprise plastic, metal, glass, or semiconductor (e.g., silicon).

In some applications, the substrate can include a backplane. The backplane includes active or passive electronics for controlling or switching power to individual pixels or light emitting devices. Including a backplane can be useful for applications such as displays, sensors, or imagers. In particular, the backplane can be configured as an active matrix, passive matrix, fixed format, direct drive, or hybrid. The display can be configured for still images, moving images, or lighting. A display including an array of light emitting devices can provide white light, monochrome light, or color-tunable light.

In addition to the charge transport layers, a device may optionally further include one or more charge-injection layers, e.g., a hole-injection layer (either as a separate layer or as part of the hole transport layer) and/or an electron-injection layer (either as a separate layer as part of the electron transport layer). Charge injection layers comprising organic materials can be intrinsic (un-doped) or doped. See, for example, U.S. Provisional Patent Application No. 60/795,420 of Beatty et al, for “Device Including Semiconductor Nanocrystals And A Layer Including A Doped Organic Material And Methods”, filed 27 Apr. 2006, which is hereby incorporated herein by reference in its entirety.

One or more charge blocking layers may still further optionally be included. For example, an electron blocking layer (EBL), a hole blocking layer (HBL), or an exciton blocking layer (eBL), can be introduced in the structure. A blocking layer can include, for example, 3-(4-biphenylyl)-4-phenyl-5-tert butylphenyl-1,2,4-triazole (TAZ), 3,4,5-triphenyl-1,2,4-triazole, 3,5-bis(4-tert-butylphenyl)-4-phenyl-1,2,4-triazole, bathocuproine (BCP), 4,4′,4″-tris{N-(3-methylphenyl)-Nphenylamino} triphenylamine (m-MTDATA), polyethylene dioxythiophene (PEDOT), 1,3-bis(5-(4-diphenylamino)phenyl-1,3,4-oxadiazol-2-yl)benzene, 2-(4-biphenylyl)-5-(4-tertbutylphenyl)-1,3,4-oxadiazole, 1,3-bis[5-(4-(1,1-dimethylethyl)phenyl)-1,3,4-oxadiazol-5,2-yl)benzene, 1,4-bis(5-(4-diphenylamino)phenyl-1,3,4-oxadiazol-2-yl)benzene, 1,3,5-tris[5-(4-(1,1-dimethylethyl)phenyl)-1,3,4-oxadiazol-2-yl)benzene, or 2,2′,2″-1,3,5-Benzinetriyl)-tris(1-phenyl-1-H-benzimidazole) (TPBi).

Charge blocking layers comprising organic materials can be intrinsic (un-doped) or doped. See, for example, U.S. Provisional Patent Application No. 60/795,420 of Beatty et al, for “Device Including Semiconductor Nanocrystals And A Layer Including A Doped Organic Material And Methods”, filed 27 Apr. 2006, which is hereby incorporated herein by reference in its entirety.

The charge injection layers (if any), and charge blocking layers (if any) can be deposited on a surface of one of the electrodes by spin coating, dip coating, vapor deposition, or other thin film deposition methods. See, for example, M. C. Schlamp, et al., J. Appl. Phys., 82, 5837-5842, (1997); V. Santhanam, et al., Langmuir, 19, 7881-7887, (2003); and X. Lin, et al., J. Phys. Chem. B, 105, 3353-3357, (2001), each of which is incorporated by reference in its entirety.

Other multilayer structures may optionally be used to improve the performance (see, for example, U.S. patent application Ser. Nos. 10/400,907 and 10/400,908, filed Mar. 28, 2003, each of which is incorporated by reference in its entirety) of the light emitting devices and displays of the invention. The performance of light emitting devices can be improved by increasing their efficiency, narrowing or broadening their emission spectra, or polarizing their emission. See, for example, Bulovic et al., Semiconductors and Semimetals 64, 255 (2000), Adachi et al., Appl. Phys. Lett. 78, 1622 (2001), Yamasaki et al., Appl. Phys. Lett. 76, 1243 (2000), Dirr et al., Jpn. J. Appl. Phys. 37, 1457 (1998), and D'Andrade et al., MRS Fall Meeting, BB6.2 (2001), each of which is incorporated herein by reference in its entirety.

Preferably, a light emitting device including an emissive material comprising a plurality of semiconductor nanocrystals is processed in a controlled (oxygen-free and moisture-free) environment, preventing the quenching of luminescent efficiency during the fabrication process.

The present invention will be further clarified by the following examples, which are intended to be exemplary of the present invention.

### EXAMPLES

### Example 1A

### Core Preparation

0.050 g CdO (99.998% purity—Alfa) and 0.066 g of ZnO (99.999% purity—Sigma Aldrich) were weighed into a three necked flask equipped with a condenser. To this was added: 4 ml tech grade oleic acid (Aldrich) and 32 ml of tech grade octadecene (ODE) (Aldrich). The contents of the flask were degassed at 80° C. for 20 minutes in vacuo (200 millitorr).

Separately 0.035 g of sulfur (99.999% Strem) was dissolved in 10 ml of tech grade ODE in a septum capped vial by stirring and heating in an oil bath to 130° C. While the sample was heating up, the pressure of the vessel was reduced to 200 millitorr until the oil bath temperature was 85° C., then further heating was continued under nitrogen. After 1 hour, when all the sulfur was dissolved, the sample was cooled to room temperature.

The contents of the three necked flask were stirred and heated, under nitrogen, to 290° C. for 20 minutes then to 310° C., until all the oxides dissolved to give a clear solution. The temperature controller was then set to 300° C. and once the temperature stabilized at 300° C., approximately 8.0 ml of S in ODE was rapidly injected. The temperature of the solution fell to about 270° C. and climbed back to 300° C. in ˜30 minutes. The reaction was stopped after 5 hours and the contents of the flask were transferred to a degassed vial under nitrogen and transferred to an inert atmosphere box for further purification.

The cores were purified by precipitation as follows. The solution was centrifuged for 5 min, 4000 rpm. After centrifuging, the supernatant liquid was poured off, retaining the solid in the centrifuge tube. 20 ml butanol was added, centrifuged, and then decanted. ˜10 ml methanol was added to the tube, centrifuged, and then decanted. ˜15 ml of anhydrous hexane was thereafter added to the solid in the centrifuge tube and the contents of the tube were mixed using a vortexer. After mixing, the contents of the tube were centrifuged. The supernatant liquid was transferred to a separate clean tube; the solids in the tube after centrifuging were discarded. Cores were precipitated from the supernatant liquid by adding excess butanol (20-25 ml) with stirring. The tube containing the precipitated cores was centrifuged, the supernatant liquid decanted, leaving precipitated cores in the tube. ˜7.5 ml anhydrous hexane were added to the precipitated cores to solvate the cores and the contents of the tube were filtered through a 0.2 micron filter. (The cores are in the filtrate.)

A 2.5 μl aliquot of the filtrate was diluted 100 fold with anhydrous hexane and a UV VIS spectrum of the diluted aliquot was measured and absorbance at 350 nm measured.

### Characterization of the Cores:

maximum peak emission—461 nm

### FWHM=15 nm

Photoluminescence quantum efficiency=17%

### Example 1B

### Shell Preparation (ZnS)

5 ml of 97% trioctylphosphine and 5 ml of oleylamine (distilled prior to use), were placed in a 4 necked flask equipped with a condenser and thermocouple. The sample was stirred and degassed at 100° C. for ˜1 hour. After introducing N₂ to the flask and reducing the temperature to 80° C., 3.8 ml of anhydrous hexane containing cores (see Example 1A above) was added and the solvent removed under vacuo for 2 hours. The temperature was raised to 170° C. and bis-trimethylsilylsulfide (92.53 mg) in 4 ml of TOP and diethylzinc (32.00 mg) in 4 ml of TOP were added from separate syringes at a rate of 50 microliters/minute. The solution in the flask was observed to develop a bluish color. After addition was complete, the solution looked cloudy. The sample was transferred via a degassed vial into an inert atmosphere box.

The cores including a ZnS shell were purified by precipitation as follows. (In this example, the precipitation step was carried out two times for each sample) as follows. ˜10 ml of anhydrous hexane was added to the liquid in the degassed vial and divided into 2 tubes. Semiconductor nanocrystals comprising a core and a ZnS shell disposed over the core were precipitated by adding 20 ml of a 3:1 anhydrous methanol/isopropanol mixture to each of the two tubes, following which the supernatant liquid was decanted, leaving the semiconductor nanocrystals in the centrifuge tubes. 3 ml anhydrous hexane were added to the semiconductor nanocrystals in each of the centrifuge tubes and the contents combined and then reprecipitated by the addition of a 3:1 anhydrous methanol/isopropanol mixture. The reprecipitated semiconductor nanocrystals were centrifuged to separate and recover the nanocrystals. After the supernatant liquid was removed, the nanocrystals were solvated in 5 ml anhydrous-hexane. The mixture including the anhydrous-hexane and the semiconductor nanocrystals from both centrifuge tubes was filtered through a 0.2 micron filter. (The overcoated cores are in the filtrate.)

### Characterization of the Core/Shell Nanocrystals:

maximum peak emission 464 nm

### FWHM=18 nm

Photoluminescence quantum efficiency ˜100%

### Example 2

### Devices Fabricated with Purified CdZnS/ZnS Core-Shell Particles

Devices #070115F and 070119A were fabricated with CdZnS/ZnS core-shell particles made in accordance with Example 1. The device was made as follows:

Glass (50 mm×50 mm) with patterned indium tin oxide (ITO) electrode on one surface (obtained from Thin Film Devices, Anaheim, Calif.) is cleaned in an oxygen plasma for about 8 minutes to remove contaminants and oxygenate the surface. The cleaning takes place in >99% oxygen under vacuum (0.1-1.5 torr). The glass is placed on a water cooled plate to help control the increase in temperature during cleaning.

A layer of hole injection material (PEDOT, obtained from H. S. Starck, GmbH, a member of the Bayer AG group of companies) (HIL) is spun onto the surface of the glass including the patterned electrode at a speed of 4000 RPM, to a thickness of about 750 Angstroms. This step is carried out under ambient conditions (i.e., not in a glove box). The PEDOT coated glass is then heated on a 120° C. hot plate in a chamber (<20 ppm water & <10 ppm oxygen), in a HEPA filter environment (approx. Class 1), in a nitrogen atmosphere for >20 minutes to dry the PEDOT. The PEDOT coated glass is then allowed to cool to room temperature.

A layer of hole transport material (N,N′-bis(3-methylphenyl)-N,N′-bis(phenyl)-spiro (spiro-TPD) (OLED grade, gradient sublimation purified) from Luminescent Technologies, Taiwan)) is then evaporated onto the PEDOT layer in a deposition chamber (an \acute{Ø}MOD chamber, obtained from Angstrom Engineering, Ottowa, Canada) after the chamber is pumped down to 10⁻⁶ torr or better.

A layer comprising 30% by weight (based on deposition rates) 4,4′-Bis(carbazol-9-yl)biphenyl (CBP) (OLED grade, gradient sublimation purified) from Luminescent Technologies, Taiwan) and (p-bis(triphenylsilyl)benzene (UGH2) (OLED grade, gradient sublimation purified) from Luminescent Technologies, Taiwan)) is then evaporated onto the spiro-TPD layer in a deposition chamber (an \acute{Ø}MOD chamber, obtained from Angstrom Engineering, Ottowa, Canada) after the chamber is pumped down to 10⁻⁶ torr or better.

The coated glass is then returned to the nitrogen environment and stamped with an ink including the CdZnS/ZnS core-shell semiconductor nanocrystals made in accordance with the Example 1 and hexane. The optical density of the dispersion of the semiconductor nanocrystals in the ink was ˜0.02. The ink was stamped onto the layer comprising using an unfeatured curved Parylene-C coated PDMS stamp using printing machine model XP-05 made by Pad Printing Machinery of Vermont.

After printing, the device was returned to the deposition chamber and pumped back down to 10⁻⁶ torr or better for evaporation of the next layer, which can be a hole blocking layer or an electron transport layer.

A layer of TPBi electron transport material from Luminescent Technologies, Taiwan is deposited.

A layer of LiF is deposited.

A layer of Al is deposited.

The deposited layers of Al and LiF are encapsulated with UV Resin T470/UR7132-SA1 from Nagase ChemteX

Each of the vapor deposited layers is patterned with use of shadow masks. After deposition of the electron transport material layer, the mask is changed before deposition of the metal cathode.

The details of the materials and layer thickness for the device of Example 2 are set forth below in the Table 1:

TABLE 1

| | Vacuum | | Thickness | |
|---|---|---|---|---|
| LAYER | (torr) | Material | (Angstroms) | |
| HIL | 0.1-1.5 | PEDOT | 750 | A |
| HTL | 9E−007 | spiro-TPD | 420 | A |
| Spacer | 5E−007 | Mixture of | 80 | A |
| CBP/UGH2 | | CBP (30% by | | |
| | | wt) and UGH2 | | |
| EMISSIVE | 0.1-1.5 | CdZnS/ZnS | 50-100 | A |
| MATERIAL | | | | |
| ETL | 1E−007 | TPBi | 500 | A |
| CATHODE | 7E−007 | LiF | 5 | A |
| TOP LAYER | 5E−007 | Al | 1000 | A |

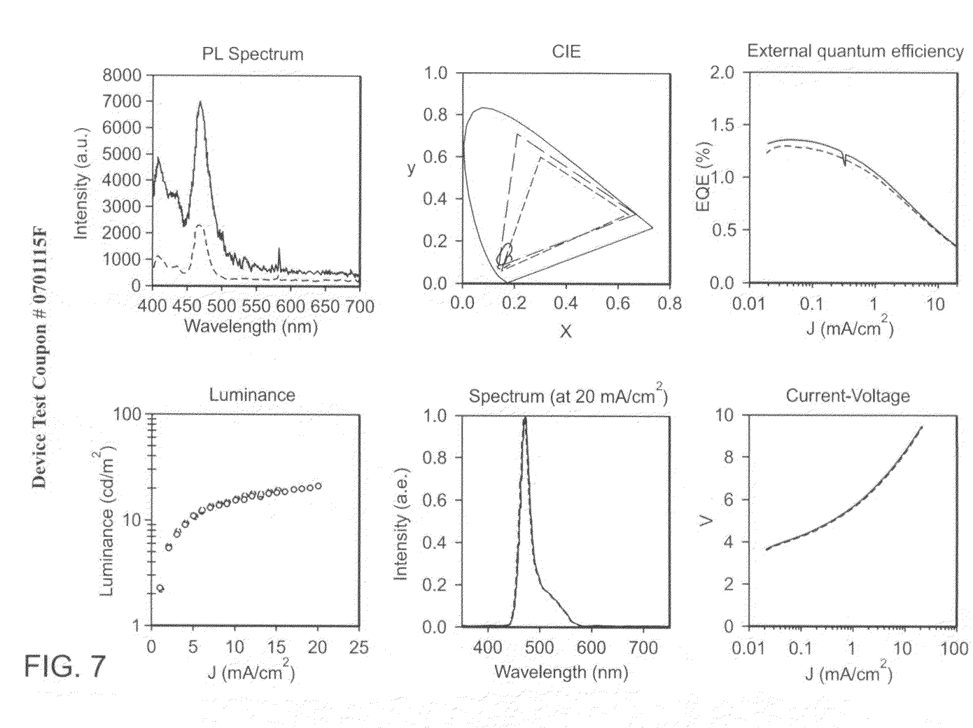

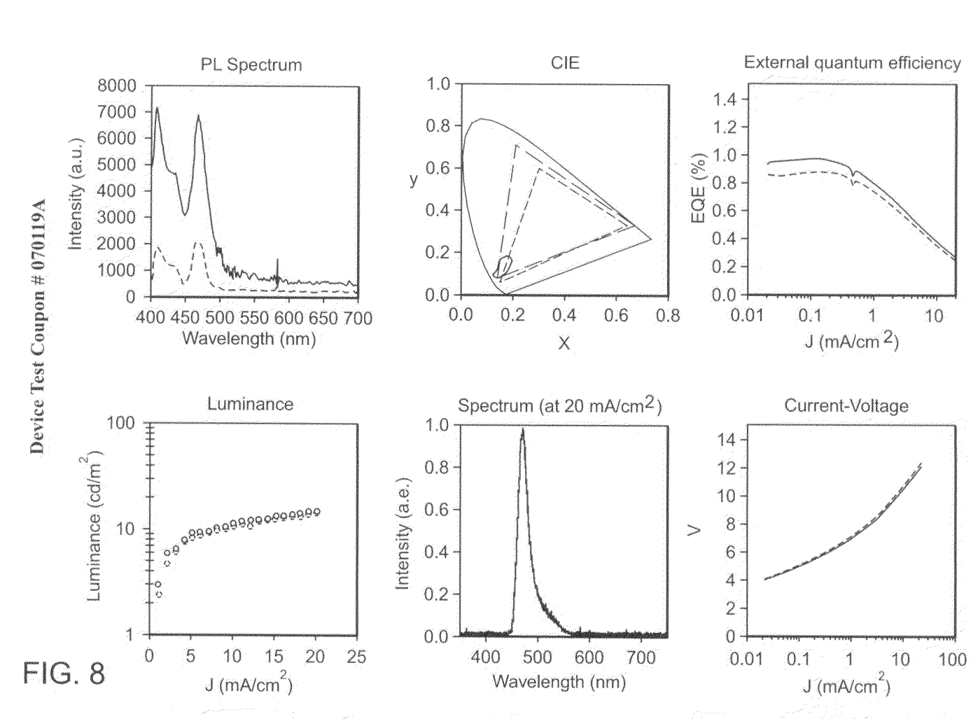

Additional data for the devices described in the Table are shown in FIGS. 7 and 8.

### Example 3

### Devices Fabricated with Purified CdZnS/ZnS Core-Shell Particles

Devices #0705181, #070518J and #070518L were fabricated with CdZnS/ZnS core-shell particles made substantially in accordance with Example 1. Substrate selection and cleaning, hole injection material selection and deposition, and hole transport material selection and deposition are performed substantially in accordance with Example 2.

The devices were made as follows:

For Devices #0705181, #070518J and #070518L, the substrates were transported from the vacuum chamber through the nitrogen environment through air ambient into a chemical vapor deposition vacuum chamber (Specialty Coating Systems PDS-2010). A 10 nm layer of Parylene-C was deposited on top of the hole transport material. The coated glass is then returned to the nitrogen environment and stamped with an ink including the CdZnS/ZnS core-shell semiconductor nanocrystals made substantially in accordance with the Example 1 and hexane. The optical density of the dispersion of the semiconductor nanocrystals in the ink was ˜0.02. The ink was stamped onto the layer comprising using an unfeatured curved Parylene-C coated PDMS stamp using printing machine model XP-05 made by Pad Printing Machinery of Vermont. After printing, Device #0705181 was returned to the deposition chamber and pumped back down to 10⁻⁶ torr or better for evaporation of the next layer, which can be a hole blocking layer or an electron transport layer. After printing, Devices #0705181J and #0705181J were transported from the vacuum chamber through the nitrogen environment through air ambient into a chemical vapor deposition vacuum chamber (Specialty Coating Systems PDS-2010). A 10 nm layer of Parylene-C was deposited on top of the semiconductor nanocrystal layer. Substrates were then returned to the deposition chamber and pumped back down to 10⁻⁶ torr or better for evaporation of the next layer, which can be a hole blocking layer or an electron transport layer. For Devices #0705181, #070518J and #070518L, a layer of TPBi electron transport material from Luminescent Technologies, Taiwan is deposited. A layer of LiF is deposited. A layer of Al is deposited.

The deposited layers of Al and LiF are encapsulated by UV Resin T470/UR7132-SA1 from Nagase ChemteX.

Each of the vapor deposited layers is patterned with use of shadow masks. After deposition of the electron transport material layer, the mask is changed before deposition of the metal cathode.

The details of the materials and layer thickness for the device of Example 3 are set forth below in the Table 2:

TABLE 2

| | Vacuum | | Thickness | |
|---|---|---|---|---|
| LAYER | (torr) | Material | (Angstroms) | |
| HIL | 0.1-1.5 | PEDOT | 750 | A |
| HTL | 9E−007 | spiro-TPD | 500 | A |
| SPACER^{a} | 0.1 | Parylene-C | 100 | A |
| EMISSIVE LAYER | 0.1-1.5 | CdZnS/ZnS | 50-100 | A |
| SPACER^{b} | 0.1 | Parylene-C | 100 | A |
| ETL | 1E−007 | TPBi | 500 | A |
| CATHODE | 7E−007 | LiF | 5 | A |
| TOP LAYER | 5E−007 | Al | 1000 | A |

^{a}For #070518I, #070518J and #070518L devices
^{b}For #070518J and #070518L devices only

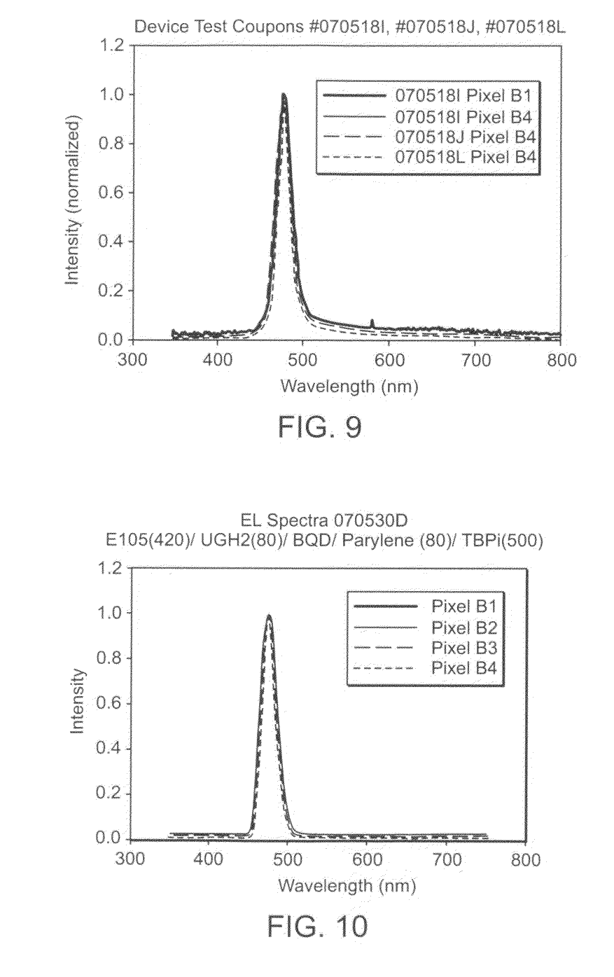

Additional data for the devices described in the Table are shown in FIG. 9.

### Example 4

### Devices Fabricated with Purified CdZnS/ZnS Core-Shell Particles

Device #070530D was fabricated with CdZnS/ZnS core-shell particles made substantially in accordance with Example 1. Substrate selection and cleaning, hole injection material selection and deposition, and hole transport material selection and deposition are performed substantially in accordance with Example 2.

The devices were made as follows:

A layer of (p-bis(triphenylsilyl)benzene (UGH2) (OLED grade, gradient sublimation purified) from Luminescent Technologies, Taiwan)) is then evaporated onto the spiro-TPD layer in a deposition chamber (an \acute{Å}MOD chamber, obtained from Angstrom Engineering, Ottowa, Canada) after the chamber is pumped down to 10⁻⁶ torr or better. The coated glass is then returned to the nitrogen environment and stamped with an ink including the CdZnS/ZnS core-shell semiconductor nanocrystals made substantially in accordance with the Example 1 and hexane. The optical density of the dispersion of the semiconductor nanocrystals in the ink was ˜0.02. The ink was stamped onto the layer comprising using an unfeatured curved Parylene-C coated PDMS stamp using printing machine model XP-05 made by Pad Printing Machinery of Vermont.

After printing, the substrate was transported from the vacuum chamber through the nitrogen environment through air ambient into a chemical vapor deposition vacuum chamber (Specialty Coating Systems PDS-2010). A 10 nm layer of Parylene-C was deposited on top of the semiconductor nanocrystal layer. Substrates were then returned to the deposition chamber and pumped back down to 10⁻⁶ torr or better for evaporation of the next layer, which can be a hole blocking layer or an electron transport layer. A layer of TPBi electron transport material from Luminescent Technologies, Taiwan is deposited. A layer of LiF is deposited. A layer of Al is deposited.

The deposited layers of Al and LiF are encapsulated.

Each of the vapor deposited layers is patterned with use of shadow masks. After deposition of the electron transport material layer, the mask is changed before deposition of the metal cathode.

The details of the materials and layer thickness for the device of Example 4 are set forth below in the Table 3:

TABLE 3

| | Vacuum | | Thickness |
|---|---|---|---|
| LAYER | (torr) | Material | (Angstroms) |
| HIL | 0.1-1.5 | PEDOT | 750 |
| HTL | 9E−007 | spiro-TPD | 420 |
| SPACER | 5E−007 | UGH2 | 80 |
| EMISSIVE LAYER | 0.1-1.5 | CdZnS/ZnS | 50-100 |
| SPACER | 0.1 | Parylene-C | 80 |
| ETL | 1E−007 | TPBi | 500 |
| CATHODE | 7E−007 | LiF | 5 |
| TOP LAYER | 5E−007 | Al | 1000 |

Additional data for the devices described in Table 4 are shown in FIG. 10.

As used herein, “top” and “bottom” are relative positional terms, based upon a location from a reference point. More particularly, “top” means furthest away from the substrate, while “bottom” means closest to the substrate. For example, for a light emitting device that optionally includes two electrodes, the bottom electrode is the electrode closest to the substrate, and is generally the first electrode fabricated; the top electrode is the electrode that is more remote from the substrate, on the top side of the light emitting material. The bottom electrode has two surfaces, a bottom surface closest to the substrate, and a top surface further away from the substrate. Where, e.g., a first layer is described as disposed or deposited “over” a second layer, the first layer is disposed further away from substrate. There may be other layers between the first and second layer, unless it is otherwise specified. For example, a cathode may be described as “disposed over” an anode, even though there are various organic and/or inorganic layers in between.

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the specification and practice of the invention disclosed herein. It is intended that the specification and examples be considered as exemplary only, with a true scope and spirit of the invention being indicated by the following claims and equivalents thereof.

1. (canceled)

2. (canceled)

3. (canceled)

4. A light emitting device comprising: a first electrode opposite a second electrode, and an emissive material disposed between the electrodes, the emissive material comprising a plurality of semiconductor nanocrystals capable of emitting light including a maximum peak emission in the blue region of the spectrum upon excitation, a first material capable of transporting charge disposed between the emissive material and the first electrode; and first spacer material disposed between the emissive material and the first electrode.

5. A light emitting device in accordance with claim 4 wherein the first spacer material is disposed between the emission material and the first material capable of transporting charge.

6. A light emitting device in accordance with claim 4 wherein at least an amount of the first spacer material is mixed in the first material capable of transporting charge.

7. A light emitting device in accordance with claim 4 further comprising a second material capable of transporting charge disposed between the emissive material and the second electrode.

8. A light emitting device in accordance with claim 6 further comprising a second spacer material disposed between the emissive material and the second material capable of transporting charge.

9. A light emitting device in accordance with claim 4, wherein at least a portion of the semiconductor nanocrystals include a core including a first semiconductor material and a shell overcoating at least a portion of the core, the shell comprising a second semiconductor material.

10. A light emitting device in accordance with claim 4 wherein at least a portion of the semiconductor nanocrystals include a ligand attached to the surface thereof.

11. A light emitting device in accordance with claim 9 wherein the core comprises a Group II-VI compound, Group II-V compound, Group III-VI compound, Group III-V compound, Group IV-VI compound, Group I-III-VI compound, Group II-IV-VI compound, or Group II-IV-V compound, Group IV element, an alloy including any of the foregoing, and/or a mixture including any of the foregoing.

12. A light emitting device in accordance with claim 9 wherein the shell comprises a Group II-VI compound, Group II-V compound, Group III-VI compound, Group III-V compound, Group IV-VI compound, Group I-III-VI compound, Group II-IV-VI compound, or Group II-IV-V compound, Group IV element, an alloy including any of the foregoing, and/or a mixture including any of the foregoing.

13. A light emitting device in accordance with claim 4 wherein at least a portion of the semiconductor nanocrystals comprise an alloy.

14. A light emitting device in accordance with claim 4 wherein at least a portion of the semiconductor nanocrystals comprise a first semiconductor material.

15. A light emitting device in accordance with claim 14 wherein the first semiconductor material comprises at least three elements.

16. A light emitting device in accordance with claim 14 wherein the first semiconductor material comprises zinc, cadmium and selenium.

17. A light emitting device in accordance with claim 9 wherein the second semiconductor material comprises zinc, cadmium, and sulfur.

18. A light emitting device in accordance with claim 9 wherein the first semiconductor material comprises at least three elements.

19. A light emitting device in accordance with claim 14 wherein the first semiconductor material comprises Zn₁₋ₓCdₓSe, wherein 0<x<1.

20. A light emitting device in accordance with claim 9 wherein the second semiconductor material comprises CdₓZn₁₋ₓS wherein 0<x<1.

21. A light emitting device in accordance with claim 9 wherein the first semiconductor material comprises cadmium, zinc, and sulfur

22. A light emitting device in accordance with claim 9 wherein the second semiconductor material comprises zinc and sulfur.

23. A light emitting device in accordance with claim 9 wherein the first semiconductor material comprises ZnₓCd₁₋ₓS, wherein 0<x<1.

24. A light emitting device in accordance with claim 9 wherein the second semiconductor material comprises ZnS.

25. A light emitting device in accordance with claim 4 wherein the first spacer material comprises a semiconductor material having a bandgap greater than the bandgap of the semiconductor nanocrystals.

26. A light emitting device in accordance with claim 4 wherein the first spacer material comprises a semiconductor material having a bandgap greater than or equal to 2.7 eV.

27. A light emitting device in accordance with claim 4 wherein the first spacer material comprises a semiconductor material having a bandgap greater than or equal to 3.2 eV.

28. A light emitting device in accordance with claim 8 wherein the second spacer material comprises a semiconductor material having a bandgap greater than the bandgap of the semiconductor nanocrystals.

29. A light emitting device in accordance with claim 8 wherein the second spacer material comprises a semiconductor material having a bandgap greater than or equal to 2.7 eV.

30. A light emitting device in accordance with claim 8 wherein the second spacer material comprises a semiconductor material having a bandgap greater than or equal to 3.2 eV.

31. A light emitting device in accordance with claim 25 wherein the semiconductor material comprises an inorganic material.

32. A light emitting device in accordance with claim 31 wherein the semiconductor material comprises silicon monoxide, silicon dioxide, silicon nitride, zinc oxide or titanium oxide.

33. A light emitting device in accordance with claim 25 wherein the semiconductor material comprises an organic material.

34. A light emitting device in accordance with claim 33 wherein the semiconductor material comprises organosilicon compoundsⁱ [diphenyldi(o-tolyl)silane (UGH1), p-bis(triphenylsilyl)benzene (UGH2), m-bis(triphenylsilyl)benzene (UGH3), and 9,9′-spirobisilaanthracene (UGH4)].

35. A light emitting device in accordance with claim 4 wherein the first spacer material comprises an insulating material.

36. A light emitting device in accordance with claim 8 wherein the second spacer material comprises an insulating material.

37. A light emitting device in accordance with claim 35 wherein the insulating material comprises an inorganic material.

38. A light emitting device in accordance with claim 35 wherein the insulating material comprises polymerized fluorocarbons, polylaurylmethacrylate (PLMA), polymethylmethacrylate (PMMA), polystyrene or parylene.

39. A light emitting device in accordance with claim 35 wherein the insulating material comprises an organic material.

40. A light emitting device in accordance with claim 36 wherein the insulating material comprises polymerized fluorocarbons, polylaurylmethacrylate (PLMA), polymethylmethacrylate (PMMA), polystyrene or parylene.

41. (canceled)

42. (canceled)

43. (canceled)

44. (canceled)

45. (canceled)

46. (canceled)

47. A light emitting device in accordance with claim 4 wherein the maximum peak emission of the device is in the range of from about 380 nm to about 500 nm.

48. A light emitting device in accordance with claim 4 wherein the maximum peak emission of the device is in the range of from about 450 nm to about 490 nm.

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. A light emitting device comprising:
a substrate;
a first electrode disposed on a substrate;
a first material capable of transporting charge disposed over the first electrode;
a second material capable of transporting charge disposed over the first material capable of transporting charge;
a second electrode disposed over the second material capable of transporting charge;
an emissive material comprising a plurality of semiconductor nanocrystals capable of emitting light including a maximum peak emission in the blue region of the spectrum upon excitation disposed between the first electrode and the second electrode; and
a first spacer material disposed between the emissive material and one of the electrodes.

103. A light emitting device in accordance with claim 102 further including a second spacer material disposed between the emissive material and the other one of the electrodes.

104. (canceled)

105. (canceled)

106. (canceled)

107. (canceled)

108. (canceled)

109. (canceled)

110. (canceled)

111. (canceled)

112. (canceled)

113. (canceled)

114. (canceled)

115. (canceled)

116. (canceled)

117. (canceled)

118. (canceled)

119. (canceled)

120. (canceled)

121. (canceled)

122. A light emitting device including an emissive material comprising semiconductor nanocrystals disposed between a first electrode and a second electrode, and a second material disposed between the electrodes, wherein the second material is optically inactive and electrically inactive when the device is operating.

123. A light emitting device in accordance with claim 122 wherein the second material is non-emissive when the device is operating.

124. (canceled)

125. (canceled)

126. (canceled)

127. A light emitting device in accordance with claim 36 wherein the insulating material comprises an inorganic material.

128. A light emitting device in accordance with claim 36 wherein the insulating material comprises an organic material.
